(19) United States
(12) Patent Application Publication
(10) Pub. No.: US 2017/0241807 A1
(43) Pub. Date: Aug. 24, 2017

(54) READOUT CIRCUIT

(71) Applicant: KABUSHIKI KAISHA TOSHIBA, Tokyo (JP)

(72) Inventors: Yohei HATAKEYAMA, Yokohama Kanagawa (JP); Tetsuro ITAKURA, Nerima Tokyo (JP); Masanori FURUTA, Odawara Kanagawa (JP)

(21) Appl. No.: 15/429,653

(22) Filed: Feb. 10, 2017

(30) Foreign Application Priority Data
Feb. 19, 2016 (JP) 2016-030213

(51) Int. Cl. G01D 5/16; H03F 3/45

(52) U.S. Cl. CPC G01D 5/16; H03F 3/45179; H03F 2200/261

(57) ABSTRACT

A readout circuit has a first transistor which have a first terminal, a second terminal, and a control terminal, a second transistor having a first terminal, a second terminal, and a control terminal, a first variable resistance having a first terminal connected to a first reference voltage line, and a second terminal connected to the first terminal of the first transistor, a first resistance having a first terminal connected to the first reference voltage line, and a second terminal connected to the first terminal of the second transistor, a second resistance having a first terminal connected to the second terminal of the first transistor, and a second terminal connected to a second reference voltage line, and a second variable resistance which has a first terminal connected to the second terminal of the second transistor, and a second terminal connected to the second reference voltage line.

### CROSS REFERENCE TO RELATED APPLICATIONS

This application is based upon and claims the benefit of priority from the prior Japanese Patent Application No. 2016-30213, filed on Feb. 19, 2016, the entire contents of which are incorporated herein by reference.

### FIELD

Embodiment of the present disclosure relate to a readout circuit.

### BACKGROUND

In a variable resistance sensor, a change in a target of detection such as light is detected as a change in a resistance value, and the change in the resistance value is read by a readout circuit. The readout circuit outputs a detection signal depending on the change in the read resistance value.

Conventionally, a Wheatstone bridge is utilized as a readout circuit. In a sensor having two forward variable resistances, which are frequently employed in a MEMS (Micro Electro Mechanical Systems) sensor, the two variable resistances are arranged diagonally to the Wheatstone bridge.

In a conventional Wheatstone bridge, when the resistance value changes, the value of current flowing through the resistance and the common-mode voltage applied to the resistance also change. Accordingly, a change in the resistance value is converted into a change in the voltage value with low efficiency. Consequently, the conventional Wheatstone bridge is subject to equivalent input noise of a subsequent circuit. This leads to a problem that the SNR (Signal to Noise Ratio) of the detection signal to be outputted is low.

### BRIEF DESCRIPTION OF THE DRAWINGS

FIG. 1 is a diagram showing an example of a readout circuit according to a first embodiment.

FIG. 2 is a diagram showing an example of a conventional readout circuit.

FIG. 3 is a diagram showing an example of an amplifier circuit of FIG. 1,

FIG. 4 is a diagram showing another example of the amplifier circuit A of FIG. 1.

FIG. 5 is a diagram showing an example of a readout circuit according to a second embodiment.

FIG. 6 is a diagram showing an example of a readout circuit according to a third embodiment.

FIG. 7 is a diagram showing an example of a readout circuit according to a fourth embodiment.

FIG. 8 is a diagram showing an example of a filter circuit of FIG. 7.

FIG. 9 is a diagram showing an example of a readout circuit according to a fifth embodiment.

FIG. 10 is a diagram showing another example of the readout circuit according to the fifth embodiment.

### DETAILED DESCRIPTION

According to one embodiment, a readout circuit has a first transistor to comprise a first terminal, a second terminal, and a control terminal applied with a bias voltage, a second transistor to comprise a first terminal, a second terminal, and a control terminal applied with the bias voltage, a first variable resistor to comprise a first terminal connected to a first reference voltage line, and a second terminal connected to the first terminal of the first transistor, a first resistor to comprise a first terminal connected to the first reference voltage line, and a second terminal connected to the first terminal of the second transistor, a second resistor to comprise a first terminal connected to the second terminal of the first transistor, and a second terminal connected to a second reference voltage line, and a second variable resistor to comprise a first terminal connected to the second terminal of the second transistor, and a second terminal connected to the second reference voltage line.

Hereinafter, embodiments of the present disclosure will be explained referring to the drawings.

### FIRST EMBODIMENT

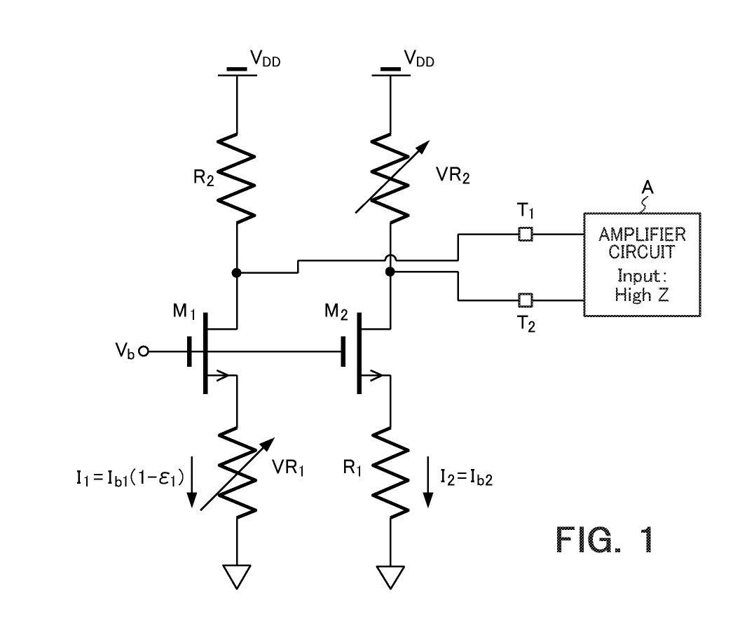

A readout circuit according to a first embodiment will be explained referring to FIGS. 1 to 4. The readout circuit according to the present embodiment reads a change in the resistance value of a variable resistance sensor. That is, the readout circuit outputs a detection signal depending on a change in the resistance value of the variable resistance sensor.

First, a configuration of the readout circuit will be explained. FIG. 1 is a diagram showing an example of a readout circuit according to the present embodiment. The readout circuit of FIG. 1 has a transistor M₁, a transistor M₂, a variable resistance VR₁, a resistance R₁, a resistance R₂, a variable resistance VR₂, an output terminal T₁, an output terminal T₂, and an amplifier circuit A.

The transistor M₁ (first transistor) is an N-channel MOSFET (Metal Oxide Semiconductor Field Effect Transistor) (hereinafter referred to as “NMOS”) having a source terminal (first terminal), a drain terminal (second terminal), and a gate terminal (control terminal). The source terminal is connected to a second terminal of the variable resistance VR₁. The drain terminal is connected to a first terminal of the resistance R₂ and the output terminal T₁. The gate terminal is applied with a predetermined bias voltage V_{b}.

The transistor M₂ (second transistor) is an NMOS having a source terminal, a drain terminal, and a gate terminal. The source terminal is connected to a second terminal of the resistance R₁. The drain terminal is connected to a first terminal of the variable resistance VR₂ and the output terminal T₂. The gate terminal is applied with the predetermined bias voltage V_{b}.

The variable resistance VR₁ (first variable resistance) is a variable resistance of a variable resistance sensor. The variable resistance VR₁ has a resistance value which changes depending on a change in a target of detection, such as light. The variable resistance VR₁ has a first terminal and a second terminal. The first terminal is connected to a ground line (first reference voltage line). That is, the first terminal is grounded. The second terminal is connected to the source terminal of the transistor M.

The resistance R₁ (first resistance) is a fixed resistance having a constant resistance value. The resistance R₁ has a first terminal and a second terminal. The first terminal is connected to the ground line. That is, the first terminal is grounded. The second terminal is connected to the source terminal of the transistor M₂.

The resistance R₂ (second resistance) is a fixed resistance having a constant resistance value. The resistance R₂ has a first terminal and a second terminal. The first terminal is connected to the drain terminal of the transistor M₁ and the output terminal T₁. The second terminal is connected to a power-supply line (second reference voltage line).

The variable resistance VR₂ (second variable resistance) is a variable resistance of a variable resistance sensor. The variable resistance VR₂ has a resistance value which changes depending on a change in a target of detection, such as light. The variable resistance VR₂ has a first terminal and a second terminal. The first terminal is connected to the drain terminal of the transistor M₂ and the output terminal T₂. The second terminal is connected to the power-supply line.

The output terminal T₁ is connected to the drain terminal of the transistor M₁, the first terminal of the resistance R₂, and a first input terminal T₃ of the amplifier circuit A. The voltage of the output terminal T₁ is inputted into the amplifier circuit A as a detection signal of the variable resistance VR₁.

The output terminal T₂ is connected to the drain terminal of the transistor M₂, the first terminal of the variable resistance VR₂, and a second input terminal T₄ of the amplifier circuit A. The voltage of the output terminal T₂ is inputted into the amplifier circuit A as a detection signal of the variable resistance VR₂.

The amplifier circuit A is a voltage amplifier circuit which amplifies differentially inputted voltage and has a high input impedance. The amplifier circuit A has input terminals T₃ and T₄ and output terminals T₅ and T₆. The input terminal T₃ is connected to the output terminal T₁. The input terminal T₄ is connected to the output terminal T₂. The amplifier circuit A amplifies detection signals (voltage signals) differentially inputted from the input terminals T₃ and T₄, and differentially outputs the amplified detection signals. The configuration of the amplifier circuit A will be mentioned in detail later.

Next, the operation of the readout circuit of FIG. 1 will be explained.

The source terminal of the transistor M₁ is connected to the ground line via the variable resistance VR₁. Accordingly, the transistor M₁ has a drain current I₁ of I_{b1}(1−ε₁). I_{b1} represents a current value of the drain current in a no-signal state, which is i.e. bias current. ε₁ represents a change rate of the resistance value of the variable resistance VR₁.

Further, the input impedance of the amplifier circuit A is sufficiently larger than the resistance value of the resistance R₂. Therefore, the output terminal T₁ has a voltage V₁ of V_{DD}−R₂I_{b1}(1−ε₁). V_{DD} represents a power-supply voltage value. R₂ represents a resistance value of the resistance R₂.

Similarly, the source terminal of the transistor M₂ is connected to the ground line via the resistance R₁. Accordingly, the transistor M₂ has a drain current 1₂ which is equal to I_{b2}. I_{b2} represents a bias current value.

Further, the input impedance of the amplifier circuit A is sufficiently larger than the resistance value of the variable resistance VR₂. Therefore, the output terminal T₂ has a voltage V₂ of V_{DD}−I_{b2}VR₂(1−ε₂). VR₂ represents a resistance value of the variable resistance VR₂ in a no-signal state. ε₂ represents a change rate of the resistance value of the variable resistance VR₂.

Here, consider a case where a resistance value VR₁ of the variable resistance VR₁ is equal to a resistance value R₁ of the resistance R₁ (i.e. VR₁=R₁=r₁) and a resistance value VR₂ of the variable resistance VR₂ is equal to a resistance value R₂ of the resistance R₂ (i.e. VR₂=R₂=r₂).

In this case, the bias current value I_{b1} of the transistor M₁ is equal to the bias current value I_{b2} of the transistor M₂ (i.e. I_{b1}=I_{b2}=I_{b}). Therefore, V₁=V_{DD}−r₂I_{b}(1−ε₁), and V₂=V_{DD}−r₂I_{b}(1+ε₂).

As will be understood from the above formulas, detection signals V₁ and V₂ are differentially outputted from the output terminals T₁ and T₂, respectively. That is, in the detection signals V₁ and V₂, changes in the power-supply voltage V_{DD}, ground voltage, and bias voltage V_{b} are canceled as a common mode phase.

Further, consider a case where characteristics of change in the resistance value of the variable resistance VR₁ are the same as characteristics of change in the resistance value of the variable resistance VR₂. At this time, the change rate ε₁ of the resistance value of the variable resistance VR₁ becomes equal to the change rate ε₂ of the resistance value of the variable resistance VR₂ (i.e. ε₁=ε₂=ε). Therefore, V₁=V_{DD}−r₂I_{b}(1−ε), and V₂=V_{DD}−r₂I_{b}(1+ε). That is, the detection signals V₁ and V₂ are differential signals each of which includes signal components depending on the change rate ε.

Here, the SNR of the readout circuit of FIG. 1 will be explained.

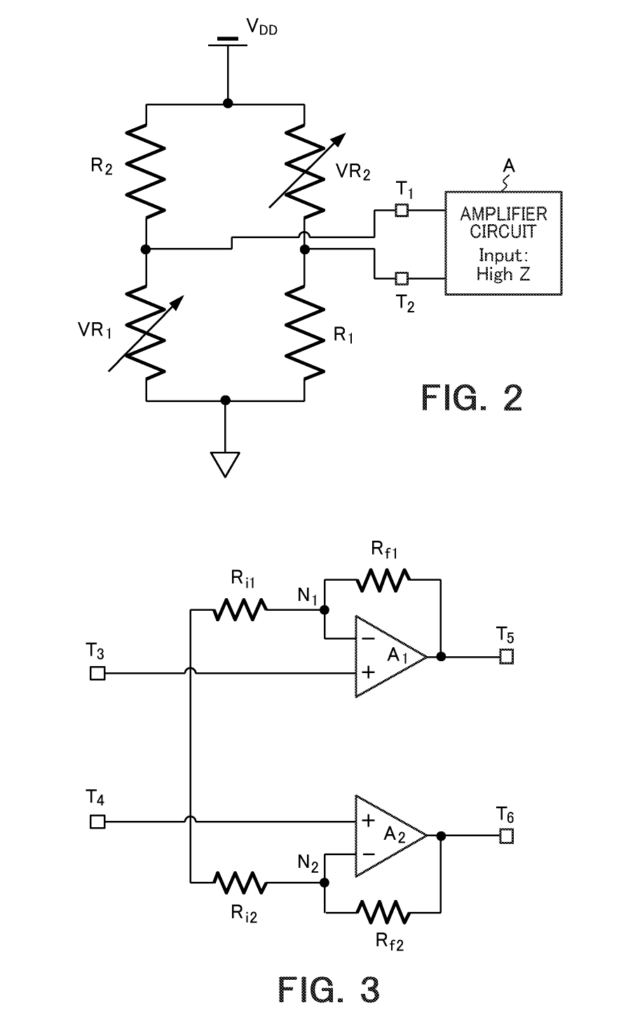

FIG. 2 is a diagram showing an example of a conventional readout circuit utilizing a Wheatstone bridge. The readout circuit of FIG. 2 can be obtained by short-circuiting the source terminal and drain terminal of the transistor M₁ and short-circuiting the source terminal and drain terminal of the transistor M₂ in the readout circuit of FIG. 1.

First, signal components included in the detection signals in the readout circuits of FIGS. 1 and 2 will be considered.

In the readout circuit of FIG. 2, when VR₁=VR₂=R₁=R₂=5 [kΩ], ε₁=ε₂=1[%], and each of the resistances (variable resistances VR₁ and VR₂ and resistances R₁ and R₂) has a voltage drop of 5 [V], V₁=5.025 [V] and V₂=4.975 [V]. That is, each of the detection signals V₁ and V₂ in the readout circuit of FIG. 2 includes signal components of 0.025 [V].

On the other hand, in the readout circuit of FIG. 1 under similar conditions, when each of the transistors M₁ and M₂ has a drain-source voltage of 1 [V], V₁=6.05 [V] and V₂=5.95 [V]. That is, each of the detection signals V₁ and V₂ in the readout circuit of FIG. 1 includes signal components of 0.05 [V].

The above shows that the signal components included in the detection signal in the readout circuit of FIG. 1 are twice as much as those included in the detection signal in the readout circuit of FIG. 2. This means that the conversion efficiency of the readout circuit of FIG. 1 is twice that of the readout circuit of FIG. 2.

Next, noise components included in the detection signals in the readout circuits of FIGS. 1 and 2 will be considered.

Noise components included in the detection signals in the readout circuit of FIG. 2 are determined by the output impedances of the output terminals T₁ and T₂, and are in proportion to (4 kTBR)^{1/2}. k represents a Boltzmann constant, T represents an absolute temperature, B represents a bandwidth, and R represents resistance components of output impedance.

Here, when defining that VR₁=VR₂=R₁=R₂=5 [kΩ], the output terminal T₂ of the readout circuit of FIG. 2 has an output impedance of K{R₁VR₂/(R₁+VR₂)}^{1/2}=1.58 K. K represents a proportional constant depending on k, T, and B. Therefore, noise components included in the detection signal V₂ can be expressed as 1.58K′. K′ is a proportional constant depending on K. This can be similarly applied to the detection signal V₁.

On the other hand, noise component Vn included in the detection signal of the readout circuit of FIG. 1 is decided by a sum of a component Vn₁ proportional to (4 kTBR)^{1/2} due to an output impedance at a drain terminal of the transistor M1 and a component Vn₂ proportional to (4 kTB/R)^{1/2} due to a current noise of a resistance connected to a source of the transistor M1. When assuming that VR₁=VR₂=R₁=R₂=5 [kΩ], the output terminal T₂ of the readout circuit of FIG. 1 has an output impedance of KVR₂^{1/2}=2.24 K, because the drain terminal of the transistor M₁ has an output impedance sufficiently larger than VR₂. Furthermore, the current noise (K/R₂)^{1/2} of the resistance connected to the source passes from the source to the drain of the transistor M1 and is converted into a voltage by VR₂, VR₂K/(R₂)^{1/2}=2.24 K. Therefore, noise components included in the detection signal V₂ can be expressed as Vn=(Vn₁²+Vn₂²)^{1/2}=3.16 K′. This can be similarly applied to the detection signal V₁.

In summary, signal components in the readout circuit of FIG. 1 are twice as much as those in the readout circuit of FIG. 2, and noise components in the readout circuit of FIG. 1 are 2 times as much as those in the readout circuit of FIG. 2. Therefore, the SNR of the readout circuit of FIG. 1 is equal to the SNR of the readout circuit of FIG. 2, but the signal level of the readout circuit of FIG. 1 is two times higher than the readout circuit of FIG. 2.

Note that noise components occurring in the transistors M₁ and M₂ are not treated in the above explanation, This is because the noise components occurring in the transistor M₁ are made negligibly small by connecting the variable resistance VR₁ between the source terminal of the transistor M₁ and the ground line. The same can be applied to the noise components occurring in the transistor M.

Concretely, by connecting the variable resistance VR₁, the transfer function of the noise components occurring in the transistor M₁ can be expressed as 1/(1+gₘ₁VR₁). gₘ₁ represents a transconductance of the transistor M₁. Since gₘ₁VR₁ is sufficiently larger than 1, the noise components occurring in the transistor M₁ are sufficiently less than the noise components included in the detection signal V₁.

Similarly, by connecting the resistance R₁, the transfer function of the noise components occurring in the transistor M₂ can be expressed as 1/(1+gₘ₂R₁). gₘ₂ represents a transconductance of the transistor M₂. Since gₘ₂R₁ is sufficiently larger than 1, the noise components occurring in the transistor M₂ are sufficiently less than the noise components included in the detection signal V₂.

As explained above, the readout circuit according to the present embodiment has a higher SNR compared to the conventional readout circuit utilizing a Wheatstone bridge, That is, the present embodiment can realize a readout circuit having a high SNR.

Further, the readout circuit according to the present embodiment differentially outputs the detection signals, which makes it possible to easily connect a differential amplifier circuit in a following stage, This makes it possible to increase the output amplitude of the detection signals.

Furthermore, in the detection signals V₁ and V₂ of the readout circuit according to the present embodiment, changes in the power-supply voltage V_{DD}, ground voltage, and bias voltage V_{b} are canceled as a common phase. Therefore, the readout circuit according to the present embodiment has a high robustness with respect to the variation in the power-supply voltage V_{DD}, ground voltage, and bias voltage V_{b}.

Still further, the readout circuit according to the present embodiment outputs voltage signals as detection signals, which eliminates the need to connect a transimpedance amplifier in a following stage. Accordingly, the present embodiment can reduce the size of circuit area, which leads to the reduction in power consumption.

FIG. 3 is a diagram showing an example of the amplifier circuit A. The amplifier circuit A of FIG. 3 has operational amplifiers A₁ and A₂, input resistances Rᵢ₁ and Rᵢ₂, feedback resistances R_{f1} and R_{f2}, the input terminals T₃ and T₄, and the output terminals T₅ and T₆.

The operational amplifier A₁ has an inverting input terminal, a non-inverting input terminal, and an output terminal. The inverting input terminal is connected to a node N₁. The non-inverting input terminal is connected to the input terminal T₃. The output terminal is connected to the output terminal T₅.

The operational amplifier A₂ has an inverting input terminal, a non-inverting input terminal, and an output terminal. The inverting input terminal is connected to a node N₂. The non-inverting input terminal is connected to the input terminal T₄. The output terminal is connected to the output terminal T₆.

The input resistance Rᵢ₁ has a first terminal and a second terminal. The first terminal is connected to a first terminal of the input terminal Rᵢ₂. The second terminal is connected to the node N₁.

The input resistance Rᵢ₂ has a first terminal and a second terminal. The first terminal is connected to the first terminal of the input terminal Rᵢ₁. The second terminal is connected to the node N₂.

The feedback resistance R_{f1} has a first terminal and a second terminal. The first terminal is connected to the node N₁. The second terminal is connected to the output terminal T₅.

The feedback resistance R_{f2} has a first terminal and a second terminal. The first terminal is connected to the node N₂. The second terminal is connected to the output terminal T₆.

The operational amplifier A₁, input resistance Rᵢ₁, and feedback resistance R_{f1} correspond to a non-inverting amplifier circuit. This non-inverting amplifier circuit has an amplification factor A₁ of 1+R_{f1}/Rᵢ₁. Therefore, signal components of the detection signal V₁ inputted from the input terminal T₃ are amplified A₁-fold and outputted from the output terminal T₅. Note that a common phase of the detection signal V₁ are amplified as the same value.

Similarly, the operational amplifier A₂, input resistance Rᵢ₂, and feedback resistance R_{f2} correspond to a non-inverting amplifier circuit. This non-inverting amplifier circuit has an amplification factor A₂ of 1+R_{f2}/Rᵢ₂. Signal components of the detection signal V₂ inputted from the input terminal T₄ are amplified A₂-fold and outputted from the output terminal T₆. Note that in-phase components of the detection signal V₂ are amplified as the same value.

In summary, the amplifier circuit A is differentially inputted with the detection signals V₁ and V₂ from the input terminals T₃ and T₄, amplifies the signal components by predetermined amplification factors, and differentially outputs the amplified detection signals from the output terminals T₅ and T₆.

With such a configuration, the amplifier circuit A can receive the detection signals from the readout circuit having a high output impedance without attenuation, and output them with a low output impedance.

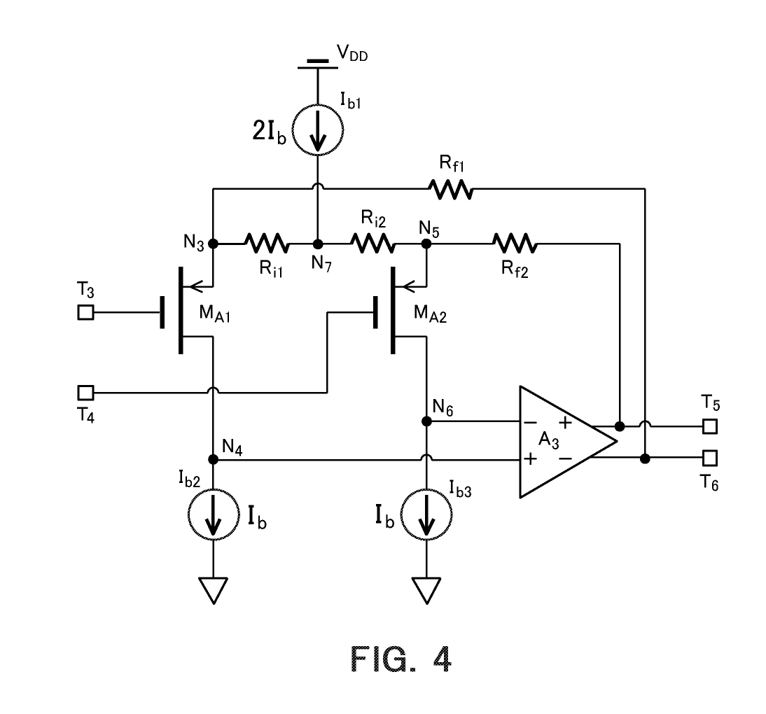

FIG. 4 is a diagram showing another example of the amplifier circuit A. The amplifier circuit A of FIG. 4 has transistors M_{A1} and M_{A2}, current sources I_{b1} to I_{b3}, the input resistances Rᵢ₁ and Rᵢ₂, the feedback resistances R_{f1} and R_{f2}, a fully-differential operational amplifier A₃, the input terminals T₃ and T₄, and the output terminals T₅ and T₆.

The transistor M_{A1} is a P-channel MOSFET (hereinafter referred to as “PMOS”) having a source terminal, a drain terminal, and a gate terminal. The source terminal is connected to a node N₃. The drain terminal is connected to a node N₄. The gate terminal is connected to the input terminal T₃. That is, the gate terminal of the transistor M_{A1} is applied with the detection signal V₁.

The transistor M_{A2} is a PMOS having a source terminal, a drain terminal, and a gate terminal. The source terminal is connected to a node N₅. The drain terminal is connected to a node N₆. The gate terminal is connected to the input terminal T₄. That is, the gate terminal of the transistor M_{A2} is applied with the detection signal V₂.

The current source I_{b1} is connected between the power-supply line and a node N₇ to supply a predetermined current to the transistors M_{A1} and M_{A2}. The current supplied by the current source I_{b1} has a current value of 2I_{b}.

The current source I_{b3} is connected between the node N₄ and the ground line to supply a predetermined current to the transistor M_{A1}. The current supplied by the current source I_{b2} has a current value of I_{b}.

The current source I_{b3} is connected between the node N₆ and the ground line to supply a predetermined current to the transistor M_{A2}. The current supplied by the current source I_{b3} has a current value of I_{b}.

The input resistance Rᵢ₁ has a first terminal and a second terminal. The first terminal is connected to the node N₃. The second terminal is connected to the node N₇.

The input resistance Rᵢ₂ has a first terminal and a second terminal. The first terminal is connected to the node N₅. The second terminal is connected to the node N₇.

The feedback resistance R_{f1} has a first terminal and a second terminal. The first terminal is connected to the node N₃. The second terminal is connected to the output terminal T₅.

The feedback resistance R_{f2} has a first terminal and a second terminal. The first terminal is connected to the node N₅. The second terminal is connected to the output terminal T₆.

The fully-differential operational amplifier A₃ has an inverting input terminal, a non-inverting input terminal, a non-inverting output terminal, and an inverting output terminal. The inverting input terminal is connected to the node N₆. The non-inverting input terminal is connected to the node N₄. The non-inverting output terminal is connected to the output terminal T₅. The inverting output terminal is connected to the output terminal T₆.

The gate terminals of the transistors M_{A1} and M_{A2}. of FIG. 4 correspond to the non-inverting input terminals of the operational amplifiers A₁ and A₂ of FIG. 3, respectively. Further, the source terminals of the transistors M_{A1} and M_{A2} of FIG. 4 correspond to the inverting input terminals of the operational amplifiers A₁ and A₂ of FIG. 3, respectively.

The amplifier circuit A can be realized with such a configuration. This makes it possible to further reduce the noise occurring in the amplifier circuit A, compared to the configuration of FIG. 3

Note that, in the above explanation, the amplifier circuit A is a differential output amplifier circuit, but it may be a single-ended output amplifier circuit. As such an amplifier circuit A, an instrumentation amplifier can be used. The instrumentation amplifier can be formed by connecting an operational amplifier in a stage following the circuit of FIG. 3, for example.

### SECOND EMBODIMENT

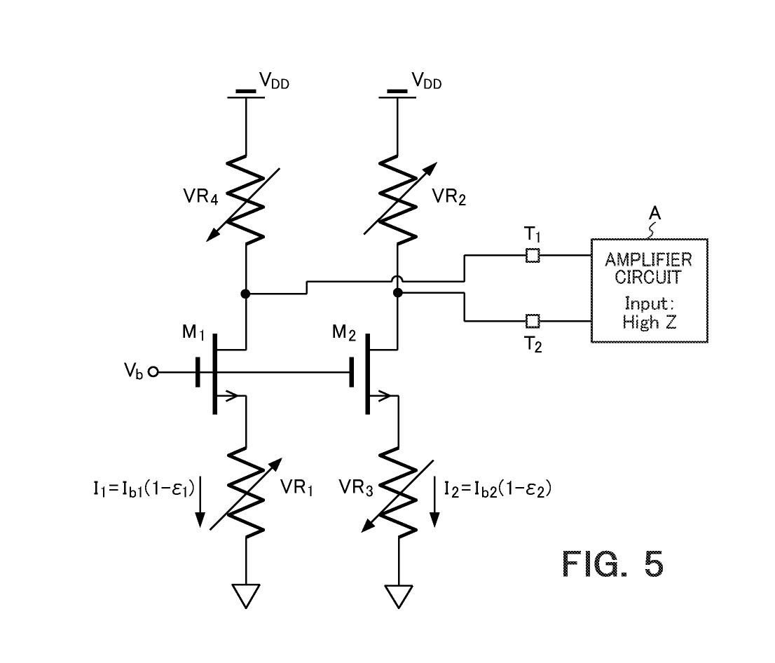

A readout circuit according to a second embodiment will be explained referring to FIG. 5.

First, a configuration of the readout circuit according to the present embodiment will be explained. FIG. 5 is a diagram showing an example of a readout circuit according to the present embodiment. The readout circuit of FIG. 5 has a variable resistance VR₃ instead of the resistance R₁, and has a variable resistance VR₄ instead of the resistance R₂. The other components are similar to those of Hg. 1.

The variable resistance VR₃ is a variable resistance of a variable resistance sensor. The variable resistance VR₃ has a resistance value which changes depending on a change in a target of detection, such as light. The variable resistance VR₃ has a first terminal and a second terminal. The first terminal is connected to the ground line. The second terminal is connected to the source terminal of the transistor M₂. The variable resistance VR₃ corresponds to a replacement for the resistance R₁.

The variable resistance VR₄ is a variable resistance of a variable resistance sensor. The variable resistance VR₄ has a resistance value which changes depending on a change in a target of detection, such as light. The variable resistance VR₄ has a first terminal and a second terminal. The first terminal is connected to the drain terminal of the transistor M₁. The second terminal is connected to the power-supply line. The variable resistance VR₄ corresponds to a replacement for the resistance R₂.

Next, the operation of the readout circuit of FIG. 5 will be explained.

The source terminal of the transistor M₁ is connected to the ground line via the variable resistance VR₁. Accordingly, the transistor M₁ has a drain current I₁ of I_{b1}(1−ε₁). This is similar to the first embodiment.

Further, the input impedance of the amplifier circuit A is sufficiently larger than the resistance value of the variable resistance VR₄. Therefore, the output terminal T₁ has a voltage V₁ of V_{DD}−VR₄(1+ε₄)I_{b1}(1−ε₁). VR₄ represents a resistance value of the variable resistance VR₄ in a no-signal state. ε₄ represents a change rate of the resistance value of the variable resistance VR₄.

Similarly, the source terminal of the transistor M₂ is connected to the ground line via the resistance VR₃. Accordingly, the transistor M₂ has a drain current I₂ of I_{b2}(1−ε₃). ε₃ represents a change rate of the resistance value of the variable resistance VR₃.

Further, the input impedance of the amplifier circuit A is sufficiently larger than the resistance value of the variable resistance VR₂. Therefore, the output terminal T₂ has a voltage V₂ of V_{DD}−VR₂(1+ε₂)I_{b2}(1−ε₃). VR₂ represents a resistance value of the variable resistance VR₂ in a no-signal state. ε₂ represents a change rate of the resistance value of the variable resistance VR₂.

Here, consider a case where the resistance value VR₁ of the variable resistance VR₁ is equal to the resistance value R₁ of the resistance R₁ (Le. VR₁=R₁=r₁), the resistance value VR₂ of the variable resistance VR₂ is equal to the resistance value R₂ of the resistance R₂ (i.e. VR₂=R₂=r₂), and characteristics of change in the resistance value of the variable resistance VR₁ are the same as characteristics of change in the resistance value of the variable resistance VR₂ (i.e. ε₁=ε₂=ε).

In this case, the bias current value I_{b1} of the transistor M₁ is equal to the bias current value I_{b2} of the transistor M₂ (i.e. I_{b1}=I_{b2}=I_{b}). Therefore, V₁=V_{DD}−r₂(1+ε₄)I_{b}(1−ε), and V₂=V_{DD}−r₂(1+ε)I_{b}(1−ε₃).

Further, consider a case where characteristics of change in the resistance value of the variable resistance VR₃ are reverse in polarity to characteristics of change in the resistance value of the variable resistance VR₂, and characteristics of change in the resistance value of the variable resistance VR₄ are reverse in polarity to characteristics of change in the resistance value of the variable resistance VR₁. At this time, the change rate ε₃ of the resistance value of the variable resistance VR₃ is reverse in sign to the change rate ε₂ of the resistance value of the variable resistance VR₂ (i.e. ε₃=−ε₂=−ε). Further, the change rate ε₄ of the resistance value of the variable resistance VR₄ is reverse in sign to the change rate ε₁ of the resistance value of the variable resistance VR₁ (i.e. ε₄=−ε₁=−ε). Therefore, V₁=V_{DD}−r₂I_{b}(1−ε)₂ and V₂=V_{DD}−r₂I_{b}(1+ε)₂. Further, when ε is minute, V₁=V_{DD}−r₂I_{b}(1−2ε) and V₂=V_{DD}−r₂I_{b}(1+2ε).

As explained above, in the present embodiment, the detection signals V₁ and V₂ are differential signals each of which includes twice the signal components of the first embodiment. Therefore, the present embodiment can further improve conversion efficiency and increase the SNR of the readout circuit compared to the first embodiment.

### THIRD EMBODIMENT

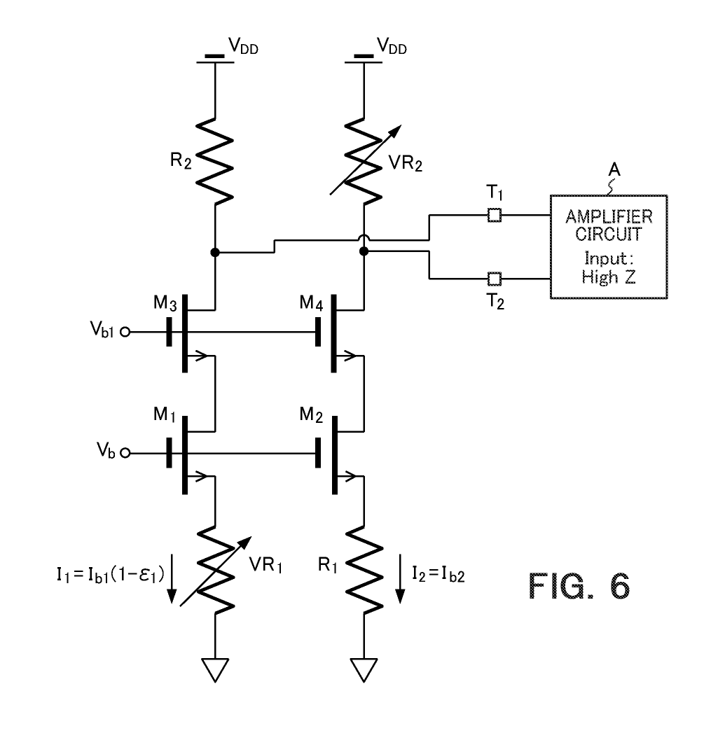

A readout circuit according to a third embodiment will be explained referring to FIG. 6. FIG. 6 is a diagram showing an example of a readout circuit according to the present embodiment. In the readout circuit of FIG. 6, a transistor M₃ is cascode-connected to the transistor M₁, and a transistor M₄ is cascode-connected to the transistor M₂. Accordingly, in the present embodiment, the drain terminals of the transistors M₁ and M₂ are connected to source terminals of the transistors M₃ and M₄, respectively. The other components are similar to those of FIG. 1.

The transistor M₃ (third transistor) is an NMOS having a source terminal, a drain terminal, and a gate terminal. The source terminal is connected to the drain terminal of the transistor M₁. The drain terminal is connected to the first terminal of the resistance R₂ and the output terminal T₁. The gate terminal is applied with a predetermined bias voltage V_{b1}. The transistor M₃ is cascode-connected to the transistor M₁.

The transistor M₄ (fourth transistor) is an NMOS having a source terminal, a drain terminal, and a gate terminal. The source terminal is connected to the drain terminal of the transistor M₂. The drain terminal is connected to the first terminal of the variable resistance VR₂ and the output terminal T₂. The gate terminal is applied with a predetermined bias voltage V_{b1}. The transistor M₄ is cascode-connected to the transistor M₂.

Here, effect produced by the readout circuit according to the present embodiment will be explained.

Generally, a MOSFET in a saturation region has a drain current ID approximating a(V_{GS}−V_{TH})₂(1+λV_{DS}), where “a” represents a proportional coefficient determined by the structure of the transistor, V_{GS} represents a gate-source voltage, V_{TH} represents a threshold voltage, λ represents a channel modulation effect coefficient, and V_{DS} represents a drain-source voltage. In the readout circuit of FIG. 1, drain-source voltages V_{DS} of the transistors M₁ and M₂ change depending on changes in the resistance values of the variable resistances VR₁ and VR₂, Accordingly, as will be understood from the above expression, the drain currents I₁ and I₂ of the transistors M₁ and M₂ change depending on changes in the resistance values of the variable resistances VR₁ and VR₂. Consequently, harmonic signals depending on changes in the drain currents I₁ and I₂ may possibly occur in the output terminals T₁ and T₂ of the readout circuit of FIG. 1.

On the other hand, in the readout circuit according to the present embodiment, since the transistor M₃ is cascade-connected to the transistor M₁, variation in the drain-source voltage of the transistor M₁ is restrained. Further, since the transistor M₄ is cascade-connected to the transistor M₂, variation in the drain-source voltage of the transistor M₂ is restrained.

Therefore, the present embodiment can restrain the harmonic signals occurring due to the changes in the drain currents I₁ and I₂ of the transistors M₁ and M₂.

### FOURTH EMBODIMENT

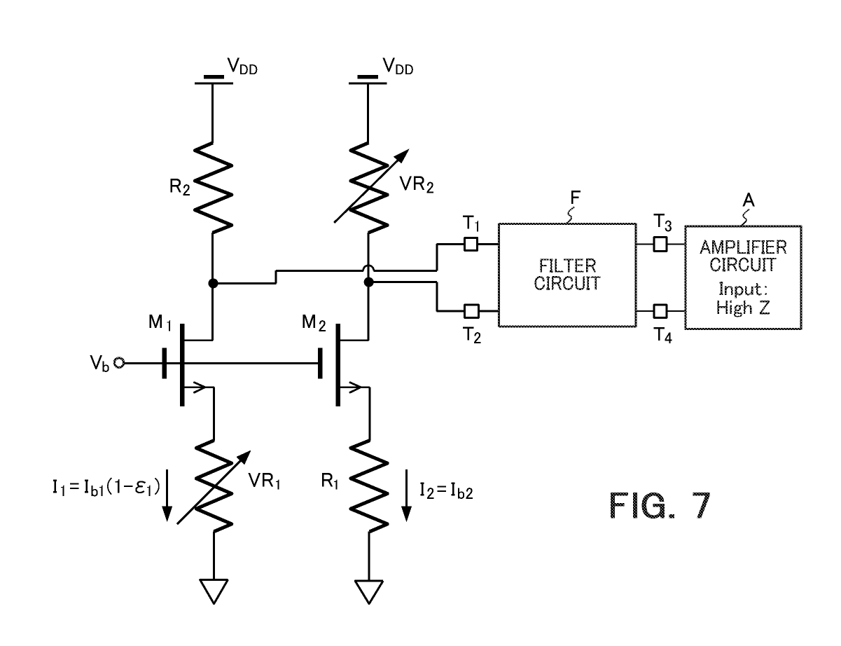

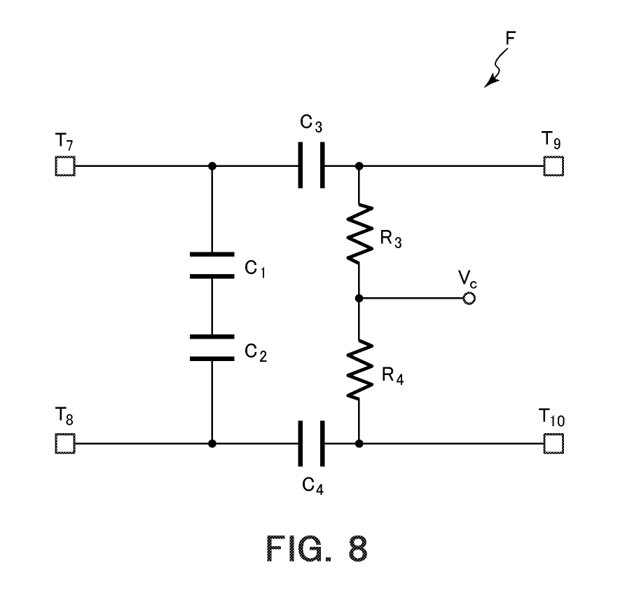

A readout circuit according to a fourth embodiment will be explained referring to FIGS. 7 and 8. FIG. 7 is a diagram showing an example of a readout circuit according to the present embodiment. The readout circuit of FIG. 7 further has a filter circuit F. In the present embodiment, the amplifier circuit A is connected in a stage following the filter circuit. The other components are similar to those of FIG. 1.

The filter circuit F is connected between the output terminals T₁ and T₂ and the input terminals T₃ and T₄. The filter circuit F passes a predetermined frequency band included in the detection signal V₁ outputted from the output terminal T₁, and inputs it into the amplifier circuit A through the input terminal T₃. Further, the filter circuit F passes predetermined frequency components included in the detection signal V₂ outputted from the output terminal T₂, and inputs them into the amplifier circuit A through the input terminal T₄. The filter circuit F is a lowpass filter, a highpass filter, or a band pass filter.

FIG. 8 is a diagram showing an example of the filter circuit F. The filter circuit F of FIG. 8 is a band pass filter functioning both as a lowpass filter and a highpass filter. The filter circuit F of FIG. 8 has input terminals T₇ and T₈, output terminals T₉ and T₁₀, capacitors C₁ to C₄, and resistances R₃ and R₄.

The input terminal T₇ (first input terminal) is connected to the output terminal T₁. The input terminal T₈ (second input terminal) is connected to the output terminal T₂. The output terminal T₉ is connected to the input terminal T₃. The output terminal T₁₀ is connected to the input terminal T₄.

The capacitor C₁ has a first terminal and a second terminal, The first terminal is connected to a second terminal of the capacitor C₂. The second terminal is connected to the input terminal T₇. The capacitor C₁ corresponds to a lowpass filter which passes low frequency components of the detection signal V₁. The time constant of this lowpass filter is determined by the capacitance value of the capacitor C₁ and the resistance value of the variable resistance VR₁.

The capacitor C₂ has a first terminal and a second terminal. The first terminal is connected to the input terminal T₈. The second terminal is connected to the first terminal of the capacitor C₁. The capacitor C₂ corresponds to a lowpass filter which passes low frequency components of the detection signal V₂. The time constant of this lowpass filter is determined by the capacitance value of the capacitor C₂ and the resistance value of the resistance R₁.

The capacitor C₃ has a first terminal and a second terminal. The first terminal is connected to the input terminal T₇. The second terminal is connected to the output terminal T₉.

The capacitor C₄ has a first terminal and a second terminal. The first terminal is connected to the input terminal T₈. The second terminal is connected to the output terminal T₁₀.

The resistance R₃ has a first terminal and a second terminal. The first terminal is connected to a second terminal of the resistance R₄ and applied with a predetermined voltage V_{C}. The second terminal is connected to the output terminal T₉.

The resistance R₄ has a first terminal and a second terminal. The first terminal is connected to the output terminal T₁₀. The second terminal is connected to the first terminal of the resistance R₃ and applied with the predetermined voltage V_{C}.

The capacitor C₃ and resistance R₃ correspond to a highpass filter which passes high frequency components of the detection signal V₁. The time constant of this highpass filter is determined by the capacitance value of the capacitor C₃ and the resistance value of the resistance R₃.

Further, the capacitor C₄ and resistance R₄ correspond to a highpass filter which passes high frequency components of the detection signal V₂. The time constant of this highpass filter is determined by the capacitance value of the capacitor C₄ and the resistance value of the resistance R₄.

A direct-current offset occurs between the detection signals V₁ and V₂ when there is an error between the resistance value of the variable resistance VR₁ and the resistance value of the resistance R₁ and when there is an error between the resistance value of the variable resistance VR₂ and the resistance value of the resistance R₂. This direct-current offset can be removed by connecting a highpass filter in a stage following the output terminals T₁ and T₂ as in the present embodiment. Consequently, passing the detection signals through the filter circuit F makes it possible to improve the SNR of the readout circuit.

Further, common-mode voltages of the filtered detection signals V₁ and V₂ outputted from the output terminals T₉ and T₁₀ become the voltage V_{C}. That is, the common-mode voltages of the detection signals V₁ and V₂ can be arbitrarily set by the voltage V_{C}. This makes it possible to make the detection signals V₁ and V₂ outputted from the output terminals T₁ and T₂ shift depending on the input voltage range of the amplifier circuit A.

### FIFTH EMBODIMENT

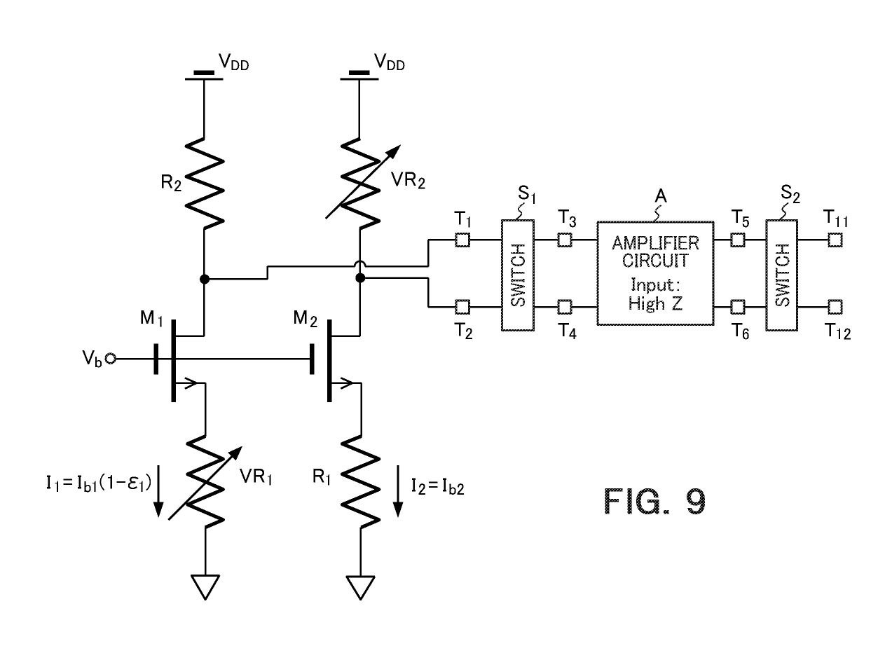

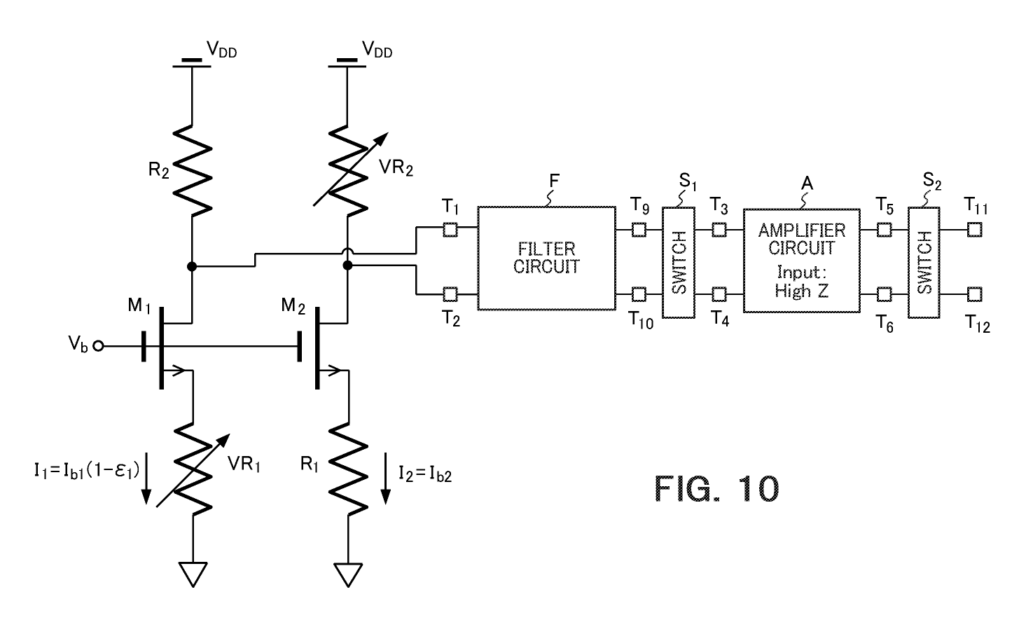

A readout circuit according to a fifth embodiment will be explained referring to FIGS. 9 and 10. The readout circuit according to the present embodiment has a chopper circuit. FIG. 9 is a diagram showing an example of a readout circuit according to the present embodiment. The readout circuit of FIG. 9 further has a route switch S₁, a route switch S₂, and output terminals and T₁₂. In the present embodiment, the amplifier circuit A is a differential output amplifier circuit. The other components are similar to those of FIG. 1,

The route switch S₁ (first route switch) (hereinafter referred to as “switch S1”) is connected in a stage preceding the amplifier circuit A. Concretely, the switch S₁ is connected between the output terminals T₁ and T₂ and the input terminals T₃ and T₄. The switch S₁ switches a first route and a second route. The first route is a route for connecting the output terminal T₁ and the input terminal T₄ and connecting the output terminal T₂ and the input terminal T₃. The second route is a route for connecting the output terminal T₁ and the input terminal T₃ and connecting the output terminal T₂ and the input terminal T₄.

The route switch S₂ (second route switch) (hereinafter referred to as “switch S2”) is connected in a stage following the amplifier circuit A. Concretely, the switch S₂ is connected between the output terminals T₅ and T₆ and the output terminals T₁₁ and T₁₂. The switch S₂ is a route switch for switching the first route and the second route. The first route is a route for connecting the output terminal T₅ and the output terminal T₁₂ and connecting the output terminal T₆ and the output terminal T₁₁. The second route is a route for connecting the output terminal T₅ and the output terminal T₁₁ and connecting the output terminal T₆ and the output terminal T₁₂.

The switches S₁ and S₂ correspond to a chopper circuit, and are synchronized with each other in the timing of switching the routes. Concretely, while the switch S₁ forms the first route, the switch S₂ also forms the first route. Further, while the switch S₁ forms the second route, the switch S₂ also forms the second route. The frequency at which the switches S₁ and S₂ switch the routes is called a switching frequency.

With such a configuration, the frequencies of the detection signals V₁ and V₂ can be shifted depending on the switching frequencies of the switches S₁ and S₂. This makes it possible to make the frequencies of the signal components of the detection signals V₁ and V₂ differ from the frequency of flicker noise occurring in the amplifier circuit A. That is, it is possible to prevent the flicker noise from being superimposed on the signal components of the detection signals V₁ and V₂. Connecting the filter circuit in a stage following the output terminals T₁₁ and T₁₂ and removing flicker noise from the detection signals V₁ and V₂ lead to the improvement of the SNR of the readout circuit.

FIG. 10 is a diagram showing another example of the readout circuit according to the present embodiment. The readout circuit of FIG. 10 has the filter circuit F explained in the fourth embodiment and the switch S₁ is connected in a stage following thereto. The other components are similar to those of FIG. 9. With such a configuration, direct-current offset and flicker noise can be removed from the detection signals V₁ and V₂. Consequently, the SNR of the readout circuit can be further improved.

Note that the readout circuit explained as an example in each of the above embodiments is formed using MOSFETs. However, the readout circuit according to each embodiment can be formed using bipolar transistors. In this case, NMOS, PMOS, source terminal, drain terminal, and gate terminal in the above explanation should be replaced with NPN-type bipolar transistor, PNP-type bipolar transistor, emitter terminal, collector terminal, and base terminal, respectively.

While certain embodiments have been described, these embodiments have been presented by way of example only, and are not intended to limit the scope of the disclosures. Indeed, the novel methods and systems described herein may be embodied in a variety of other forms; furthermore, various omissions, substitutions and changes in the form of the methods and systems described herein may be made without departing from the spirit of the disclosures. The accompanying claims and their equivalents are intended to cover such forms or modifications as would fall within the scope and spirit of the disclosures.

1. A readout circuit comprising:
a first transistor to comprise a first terminal, a second terminal, and a control terminal applied with a bias voltage;
a second transistor to comprise a first terminal, a second terminal, and a control terminal applied with the bias voltage;
a first variable resistor to comprise a first terminal connected to a first reference voltage line, and a second terminal connected to the first terminal of the first transistor;
a first resistor to comprise a first terminal connected to the first reference voltage line, and a second terminal connected to the first terminal of the second transistor;
a second resistor to comprise a first terminal connected to the second terminal of the first transistor, and a second terminal connected to a second reference voltage line; and
a second variable resistor to comprise a first terminal connected to the second terminal of the second transistor, and a second terminal connected to the second reference voltage line.

2. The readout circuit of claim 1, wherein a resistance value of the first variable resistor in a no-signal state is equal to a resistance value of the first resistor.

3. The readout circuit of claim 1, wherein a resistance value of the second variable resistor in a no-signal state is equal to a resistance value of the second resistor.

4. The readout circuit of claim 1, wherein a change rate of a resistance value of the first variable resistor is equal to a change rate of a resistance value of the second variable resistor.

5. The readout circuit of claim 1,
wherein the first resistor is a third variable resistor, and
the second resistor is a fourth variable resistor.

6. The readout circuit of claim 5,
wherein a change rate of a resistance value of the first variable resistor is reverse in sign to a change rate of a resistance value of the fourth variable resistor, and
a change rate of a resistance value of the second variable resistor is reverse in sign to a change rate of a resistance value of the third variable resistor.

7. The readout circuit of claim 1, further comprising:
a third transistor to be cascode-connected to the first transistor; and
a fourth transistor to be cascode-connected to the second transistor.

8. The readout circuit of claim 1, further comprising a filter circuit to comprise a first input terminal connected to the first terminal of the second resistor, and a second input terminal connected to the first terminal of the second variable resistor.

9. The readout circuit of claim 8, further comprising an amplifier circuit to be connected in a stage following the filter circuit.

10. The readout circuit of claim 8, further comprising:
a first route switch to be connected in a stage following the filter circuit;
an amplifier circuit to be connected in a stage following the first route switch; and
a second route switch to be connected in a stage following the amplifier circuit.

11. The readout circuit of claim 1, further comprising an amplifier circuit to comprise a first input terminal connected to the first terminal of the second resistor, and a second input terminal connected to the first terminal of the second variable resistor.

12. The readout circuit of claim 1, further comprising:
a first route switch to comprise a first input terminal connected to the first terminal of the second resistor, and a second input terminal connected to the first terminal of the second variable resistor;
an amplifier circuit to be connected in a stage following the first route switch; and
a second route switch to be connected in a stage following the amplifier circuit.
